(19) United States
(12) Patent Application Publication
(10) Pub. No.: US 2023/0309283 A1
(43) Pub. Date: Sep. 28, 2023

(54) ELECTROMAGNETIC WAVE ABSORBING MATERIAL, ELECTROMAGNETIC WAVE ABSORBING COATING MATERIAL, ELECTRONIC DEVICE AND RESIN COMPONENT

(71) Applicants: Seiki CHIBA, Meguro-ku, Tokyo (JP); Mikio WAKI, Sakura-shi, Tochigi (JP); ZEON CORPORATION, Chiyoda-ku, Tokyo (JP)

(72) Inventors: Seiki CHIBA, Meguro-ku, Tokyo (JP); Mikio WAKI, Sakura-shi, Tochigi (JP); Mitsugu UEJIMA, Chiyoda-ku, Tokyo (JP); Makoto TAKESHITA, Chiyoda-ku, Tokyo (JP)

(73) Assignees: Seiki CHIBA, Meguro-ku, Tokyo (JP); Mikio WAKI, Sakura-shi, Tochigi (JP); ZEON CORPORATION, Chiyoda-ku, Tokyo (JP)

(21) Appl. No.: 18/002,685

(22) PCT Filed: May 27, 2021
(86) PCT No.: PCT/JP2021/020255

§ 371 Date: Dec. 21, 2022

(30) Foreign Application Priority Data
Jul. 7, 2020 (JP) 2020-116779

(51) Int. Cl. H05K 9/00

(52) U.S. Cl. CPC H05K 9/0088; H05K 9/009; H05K 9/0083; C08K 3/041

(57) ABSTRACT

An electromagnetic wave absorber includes ground carbon particles derived from carbon nanotubes. With such a configuration, the electromagnetic wave absorber achieves both stretchability and electrical conductivity.

### TECHNICAL FIELD

The present invention relates to an electromagnetic wave absorbing material, an electromagnetic wave absorbing coating material, an electronic device, and a resin component.

### BACKGROUND ART

Using electromagnetic wave absorbers has been proposed as a means to reduce leakage of electromagnetic waves from devices such as electronic devices and malfunctions of electronic devices caused by external electromagnetic waves. Patent Document 1 discloses an electromagnetic wave absorber made of silicone rubber to which carbon nanotubes are added.

### TECHNICAL REFERENCE

### Patent Document

Patent Document 1: JP-A-2011-233834

### SUMMARY OF THE INVENTION

### Problems to be Solved by the Invention

For certain applications, electromagnetic wave absorbers are required to have considerable stretchability and to be formable into various shapes. It is desirable that electromagnetic wave absorbers maintain the electrical conduction network within itself when they are expanded or contracted or formed into various shapes. Carbon nanotubes contained in electromagnetic wave absorbers have relatively high electrical conductivity, but are prone to become rigid or stiff. Thus, when the shape of the electronic device changes due to mechanical stress or thermal expansion, cracks may be formed in the electromagnetic wave absorber, which may damage the network and deteriorate the performance.

The present invention has been proposed under the above-noted circumstances, and an object of the present invention is to provide an electromagnetic wave absorber, an electromagnetic wave absorbing coating, an electronic device, and a resin component that achieve both stretchability and electrical conductivity.

### Means for Solving the Problems

An electromagnetic wave absorber provided according to a first aspect of the present invention includes ground carbon particles derived from carbon nanotubes.

In a preferred embodiment of the present invention, the ground carbon particles have a particle size of 0.5 μm to 1.5 μm as measured by dynamic light scattering and a particle size of 15 μm to 70 μm as measured by laser scattering.

In a preferred embodiment of the present invention, a difference between the particle size as measured by dynamic light scattering and the particle size as measured by laser scattering of the ground carbon particles is 15 μm or larger.

In a preferred embodiment of the present invention, the electromagnetic wave absorber is formed into a sheet.

In a preferred embodiment of the present invention, the electromagnetic wave absorber is formed into a sheet made up of a plurality of laminated layers.

In a preferred embodiment of the present invention, the layers include a layer containing the ground carbon particles at a higher concentration than remaining one or ones of the layers.

In a preferred embodiment of the present invention, the layers include a layer that absorbs electromagnetic waves in a frequency band different from the layer containing the ground carbon particles at a higher concentration.

In a preferred embodiment of the present invention, the layers include at least one of a layer containing a magnetic material and a layer containing high dielectric.

An electromagnetic wave absorbing coating provided according to a second aspect of the present invention includes ground carbon particles derived from carbon nanotubes.

In a preferred embodiment of the present invention, the ground carbon particles have a particle size of 0.5 μm to 1.5 μm as measured by dynamic light scattering and a particle size of 15 μm to 70 μm as measured by laser scattering.

In a preferred embodiment of the present invention, a difference between the particle size as measured by dynamic light scattering and the particle size as measured by laser scattering of the ground carbon particles is 15 μm or larger.

An electronic device provided according to a third aspect of the present invention includes an electromagnetic wave absorbing coating applied thereto, the coating being provided according the second aspect of the present invention.

A resin component provided according to a fourth aspect of the present invention includes an electromagnetic wave absorbing coating applied thereto, the coating being provided according the second aspect of the present invention.

### Advantages of the Invention

According to the prevent invention, both stretchability and electrical conductivity are achieved.

Other features and advantages of the present invention will become clearer from the detailed description given below with reference to the accompanying drawings.

### BRIEF DESCRIPTION OF THE DRAWINGS

FIG. 1 is a sectional view showing an example of an electromagnetic wave absorber according to the present invention;

FIG. 2 is a flowchart of an example of a method for manufacturing an electromagnetic wave absorber according to the present invention;

FIG. 3 is a graph showing the measurement results of the particle size of ground carbon particles in an electrode layer as an example of an electromagnetic wave absorber according to the present invention;

FIG. 4 is a graph showing the measurement results of the particle size of ground carbon particles in an electrode layer as an example of an electromagnetic wave absorber according to the present invention;

FIG. 5 is a sectional view showing another example of an electromagnetic wave absorber according to the present invention;

FIG. 6 is a sectional view showing still another example of an electromagnetic wave absorber according to the present invention;

FIG. 7 is a sectional view showing still another example of an electromagnetic wave absorber according to the present invention;

FIG. 8 is a sectional view showing still another example of an electromagnetic wave absorber according to the present invention; and

FIG. 9 is a sectional view showing an example of an electronic device for which an electromagnetic wave absorbing coating according to the present invention is used.

### MODE FOR CARRYING OUT THE INVENTION

Preferred embodiment of the present invention are described below with reference to the accompanying drawings.

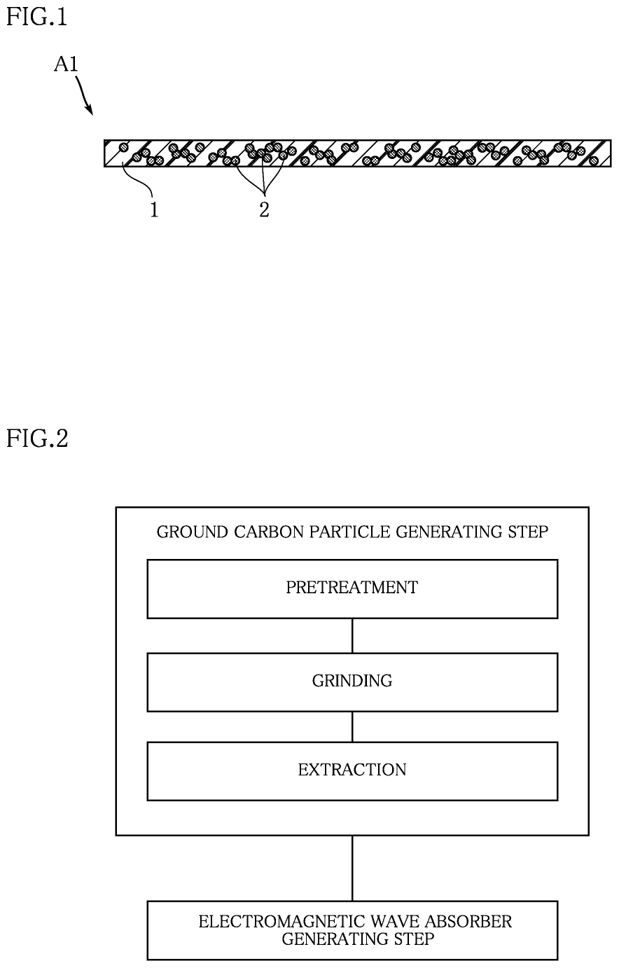

FIG. 1 shows an example of electromagnetic wave absorber according to the present invention. The electromagnetic wave absorber A1 of the present embodiment includes a substrate 1 and ground carbon particles 2.

The applications of the electromagnetic wave absorber A1 are not limited. For example, the electromagnetic wave absorber may be used as a component of an electromagnetic shield for preventing leakage and entry of electromagnetic waves, or as a structural component of an electronic device. Also, the frequency band of electromagnetic waves absorbed by the electromagnetic wave absorber A1 is not limited. The electromagnetic wave absorber A1 of the present embodiment is formed into a sheet.

The substrate 1, which serves to maintain the sheet shape of the electromagnetic wave absorber A1, is made of an insulating material. Preferably, the substrate 1 is made of a relatively flexible and stretchable material. Examples of the material of the substrate 1 are described below.

An example of the material of the substrate 1 is elastomer. The substrate includes one or more types of elastomers (polymer compounds with rubber-like elasticity). The types of elastomer are not limited, but include thermoset elastomer and thermoplastic elastomer, for example. Specific examples of elastomer include Quintac (registered trademark) (Styrene-isoprene block copolymer) available from Zeon Corporation.

The types of thermoset elastomers are not limited, but include natural rubber, synthetic rubber, silicone rubber elastomer, urethane rubber elastomer, and fluororubber elastomer, for example.

Examples of thermoplastic elastomers include copolymers of aromatic vinyl monomers and conjugated diene monomers. Specifically, examples of copolymers of aromatic vinyl monomers and conjugated diene monomers include: diblock polymers such as styrene-butadiene block copolymer and styrene-isoprene block polymer; triblock polymers such as styrene-butadiene-styrene block polymer, styrene-isoprene-styrene (SIS) block polymer, styrene-butadiene-isoprene block polymer, and styrene-isobutylene-styrene (SIBS) block polymer; styrene-containing multi-block polymers such as styrene-butadiene-styrene-butadiene block polymer, styrene-isoprene-styrene-isoprene block polymer, styrene-butadiene-isoprene-styrene block polymer, styrene-butadiene-styrene-isoprene block polymer, and styrene-isobutylene-butadiene-styrene block polymer; and their hydrogenated or partially hydrogenated additives. Of these, block polymers such as SIS are preferably used.

The ground carbon particles 2 are contained in the substrate 1 to impart electrical conductivity to the electromagnetic wave absorber A1 at least locally and perform the function of absorbing electromagnetic waves. The electromagnetic wave absorption by the ground carbon particles 2 is due to the resistive component of the conduction network constituted by the ground carbon particles 2, the RC component of the conduction network, or magnetic attenuation with heat generation, for example. Ground carbon particles 2 are particles derived from carbon nanotubes and obtained by grinding carbon tubes. Note that the electromagnetic wave absorber A1 is not limited to that containing ground carbon particles 2 alone. In addition to the ground carbon particles 2, particles of ferrite or particles of high dielectric may be contained. Examples of high dielectric include barium titanate, strontium titanate, calcium titanate, magnesium titanate, zinc titanate, lanthanum titanate, neodymium titanate, lead titanate, barium zirconate, calcium zirconate, barium tin oxide, calcium tin oxide and magnesium silicate, and these may be used alone or in mixtures of two or more.

FIG. 2 shows an example of a method for manufacturing the electromagnetic wave absorber A1. The manufacturing method of the present embodiment includes a ground carbon particle generating step and an electromagnetic wave absorber generating step. In the ground carbon particle generating step, ground carbon particles 2 derived from carbon nanotubes are generated by grinding carbon nanotubes. In the electromagnetic wave absorber generating step, the electromagnetic wave absorber A1 constituted by the substrate 1 and the ground carbon particles 2 is formed. The electromagnetic wave absorber generating step is performed by conventional techniques such as a sheet forming process or an application process, using the ground carbon particles 2 obtained by the ground carbon particle generating step and an insulating material in a paste or liquid form to become the substrate 1.

### EXAMPLE

Example of ground carbon particle generating step is described below. Note that the ground carbon particle generating step of the present invention is not limited, and any techniques capable of generating the ground carbon particles that satisfy the conditions described later can be employed.

### Pretreatment

First, single-wall carbon nanotubes (hereinafter SWCNT: e.g., SG101 available from Zeon Corporation) were mixed and dispersed in a solvent so that the content is 0.35 wt %. As the solvent, MEK (methyl ethyl ketone) was used. The solution was dispersed using a high-pressure homogenizer to obtain a SWCNT dispersion (first dispersion).

Next, the SWCNT dispersion was left at a liquid temperature of 20 to 40° C. to remove the solvent. Then, stirring using a tool such as a glass stirring rod is performed until it became powdery.

### Grinding

The SWCNTs in a powdery state were ground by a planetary ball mill. A solvent was added to the ground SWCNT powder, and dispersion using a high-pressure homogenizer was performed again. In this process, CyH (cyclohexane) was used as the solvent. The SWCNT content was 0.07 to 0.15 wt %. The SWCNT dispersion after this re-dispersion (second dispersion) was transferred to a container such as a glass container and subjected to ultrasonic vibration. The dispersion was then left for 24 hours and checked for separation of SWCNTs from the solvent. When such separation was observed, the dispersion was subjected to ultrasonic vibration again.

### Extraction

After the confirmation that there was no separation between SWCNTs and the solvent, the dispersion was further subjected to ultrasonic vibration. The SWCNT dispersion was then left for about 30 minutes, and the top portion near the liquid surface of the SWCNT dispersion was extracted into a separate container by sucking up using a tool such as a syringe.

### Comparative Examples

As Comparative Example 1, a SWCNT dispersion was prepared by dispersing unground SWCNTs in CyH as a solvent. For Comparative Examples 2 and 3, common types of carbon black was prepared. The nominal particle size of the carbon black provided by the manufacture was 15 nm to 55 nm. As Comparative Example 2, a carbon black dispersion was prepared using CyH as a solvent, as in Example. As Comparative Example 3, a carbon black dispersion was prepared using MEK as a solvent.

### Pre-Dilution before Particle Size Measurement

(1-1) From each dispersion of Example and Comparative Example 1 to 3, a 2 ml sample was collected into a glass vessel, and isopropyl alcohol (IPA: Kanto Chemical, Cica Grade 1) was added to each sample to obtain a pre-diluted solution.

(1-2) The pre-diluted solution in each vessel was stirred with e.g., a magnetic stirrer, and then subjected to ultrasonication under the following conditions: the ultrasonic frequency was 39 kHz, the output power of 100 W, and the irradiation time of 3 minutes.

(1-3) The particle size measurement noted below were performed within 10 minutes after the ultrasonication.

### Dynamic Light Scattering Method

(2-1) For measurement by dynamic light scattering, a measuring device of Zetasizer Nano series available from Malvern was used. The device was appropriately calibrated in advance using size standard particles (LTX3060A, LTX3200A) to reduce measurement errors to the order of 2% or less.

(2-2) One ml of each pre-diluted solution was put into a 12 mm square glass cell (PSC1115), and the cells were set in the device. Each glass cell was closed with a cap.

(2-3) For the particle type settings, the refractive index was set at 2.0, and the imaginary part was set at 0.850.

(2-4) For the solvent type settings, 2-Propanol was selected, the refractive index was set at 1.3750, and the viscosity was set at 2.038.

(2-5) The measurement temperature was set at 25° C.

(2-6) Each measurement was set to start 60 seconds after the measurement temperature was reached.

(2-7) The cell type was set to select “glass cuvette”.

(2-8) The detector angle for measurement was set at 173°.

(2-9) The duration of each measurement was set to select “Automatic”.

(2-10) The number of times to repeat measurement was set at 3.

(2-11) The “Measurement Position” setting was set to select “Seek for measurement position” to automatically determine an appropriate position.

(2-12) The model for smoothing the particle size distribution was set to select “General Purpose”.

(2-13) Z-Average was selected to take the average of three measurements as a measurement value.

### Laser Scattering Method

(3-1) For measurement by laser scattering, Mastersizer 3000 available from Malvern was used as a measurement device.

(3-2) For the particle type settings, the refractive index was set at 2.0, and the imaginary part was set at 0.850.

(3-3) For solvent type settings, ethanol was selected, and the refractive index was set at 1.3600.

(3-4) Ethanol (Kanto Chemical, Cica Grade 1) was used as the solvent in the measurement.

(3-5) A prescribed amount of ethanol was charged into a dispersion unit of the device and the unit was circulated in the device for 120 seconds.

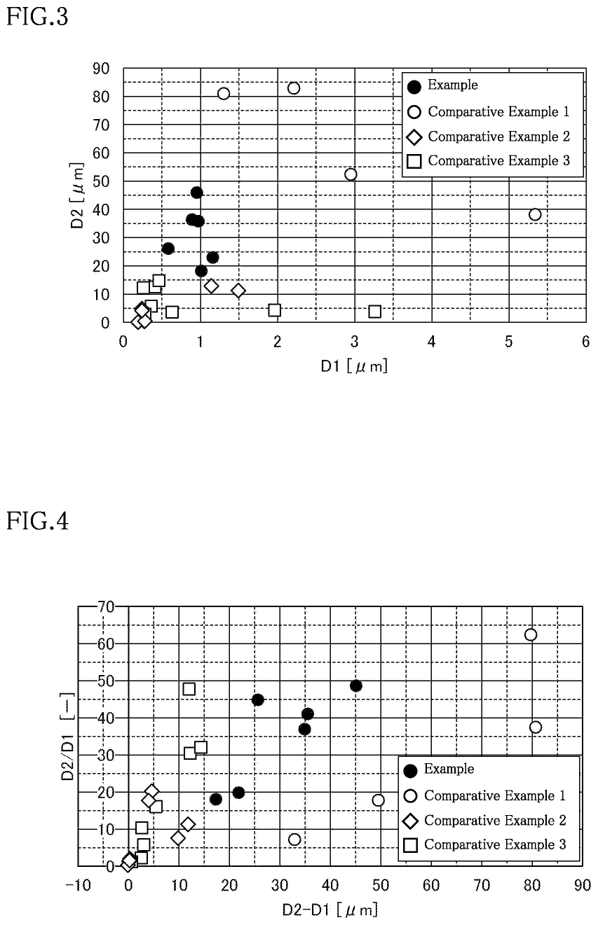

FIG. 3 shows the results of particle size measurement by dynamic light scattering and laser scattering. As shown in FIG. 3, the particle size D1 as measured by dynamic light scattering was distributed in the range of 0.5 μm to 1.5 μm for the Example. This particle size was distributed in the range of 1.3 μm to 5.4 μm for Comparative Example 1, and distributed in the range of 0.1 μm to 1.5 μm for Comparative Examples 2 and 3. The particle size D2 as measured by laser scattering was at least 15 μm and at most 50 μm for the Example. This particle size was 35 μm or larger for Comparative Example 1, and 15 μm or smaller for Comparative Examples 2 and 3.

FIG. 4 is a graph plotting the results of particle size measurement by dynamic light scattering and laser scattering as follows. The horizontal axis represents the difference between the particle size D2 and the particle size D1 (D2−D1). The difference (D2−D1) was 15 μm or larger for the Example. The difference was 32 μm or larger for Comparative Example 1. The difference was distributed in the range of 0.1 μm to 15 μm for Comparative Examples 2 and 3. The vertical axis represents the ratio of the particle size D2 to the particle size D1 (D2/D1). The ratio (D2/D1) was 15 or larger for the Example. The ratio was distributed in the range of 7 to 63 for Comparative Example 1. The ratio was distributed in the range of 0.3 to 48 for Comparative Examples 2 and 3.

As seen from the comparison between Example and Comparative Examples 1 to 3, Example satisfies the condition (hereinafter Condition 1) that the particle size D1 as measured by dynamic light scattering ranges from 0.5 μm to 1.5 μm and the particle size D2 as measured by laser light scattering is at least 15 μm and at most 50 μm, while none of Comparative Examples 1 to 3 satisfies this condition. Also, as will be understood from FIG. 4, Example alone satisfies both the Condition 1 and either of the condition (hereinafter Condition 2) that the difference (D2−D1) between the particle size D1 as measured by dynamic light scattering and the particle size D2 as measured by laser light scattering is 15 μm or larger and the condition (hereinafter Condition 3) that the ratio (D2/D1) of the particle size D2 as measured by laser light scattering to the particle size D1 as measured by dynamic light scattering is 15 or larger.

### Examples for Flexibility Evaluation

For the electromagnetic wave absorber A1, a test to evaluate the stretchability was performed. The test results are described below.

As examples for flexibility evaluation, Flexibility Evaluation Examples 1, 2 and 3 with mixing percentages of 0.5 wt %, 10 wt %, and 30 wt % of ground carbon particles 2, respectively, were prepared. The electromagnetic wave absorber A1 was formed into sheets each measuring 30 mm×15 mm and 100 μm thick. As a bending test, each sheet of electromagnetic wave absorber A1 was bent 360°, and the generation of cracks was checked. Also, as a stretching test, a 5 mm portion at each end of the electromagnetic wave absorber A1 in the longitudinal direction was fixed with a chuck made of glass epoxy resin, and the portion (20 mm in length) of the electromagnetic wave absorber A1 excluding the fixed portions was stretched by 10% to check for generation of cracks.

TABLE 1

| | Flexibility | Flexibility | Flexibility |
|---|---|---|---|
| | Evaluation | Evaluation | Evaluation |
| | Example 1 | Example 2 | Example 3 |
| | (Mixing | (Mixing | (Mixing |
| | Percentage: | Percentage: | Percentage: |
| | 0.5 wt %) | 10 wt %) | 30 wt %) |
| Bending test | Good | Good | Good |
| Stretching test | Good | Good | Good |

Table 1 shows the evaluation test results of Evaluation Examples 1 to 3. As shown in Table 1, all of the Flexibility Evaluation Examples 1 to 3 were found to have good flexibility, with no cracks generated in the bending test and the stretching test.

### Examples for Electromagnetic Wave Characteristics Evaluation

For the electromagnetic wave absorber A1, a test to evaluate the absorption and shielding of electromagnetic waves (electromagnetic wave characteristics) was performed. The test results are described below. Note that the thickness of the electromagnetic wave absorber A1 was 400 μm.

As examples for electromagnetic wave characteristics evaluation, Electromagnetic Wave Characteristics Evaluation Examples 1, 2 and 3 with mixing percentages of 0.5 wt %, 10 wt %, and 30 wt % of ground carbon particles 2, respectively, were prepared. For these Electromagnetic Wave Characteristics Evaluation Examples 1, 2 and 3, the test was performed using three different methods depending on the frequency bands, i.e., the KEC method (0.5 MHZ to 1000 MHz), the DFFC (Dual Focus Flat Cavity) method (1 GHz to 8.5 GHz), and the FS (free-space) method (60 GHz to 90 GHz). By the KEC method, the attenuations of electric field (Table 2) and magnetic field (Table 3) were measured. By the DFFC method (Table 4) and the FS method, the shielding and transmission of electromagnetic waves were measured. For the FS method, the results of absorption characteristics (Table 5) and shielding characteristics (Table 6) are shown. In each table, attenuation is shown in decibels.

TABLE 2

| | | Electromagnetic | | Electromagnetic | Electromagnetic |
|---|---|---|---|---|---|
| | | Wave | | Wave | Wave |
| | | Characteristics | | Characteristics | Characteristics |
| | | Evaluation | | Evaluation | Evaluation |
| | | Example 1 | | Example 2 | Example 3 |
| KEC method | | (Mixing | | (Mixing | (Mixing |
| (Electric Field) | | Percentage: | | Percentage: | Percentage: |
| Frequency | | 0.5 wt %) | | 10 wt %) | 30 wt %) |
| 1 | MHz | 21 | dB | 60 dB or higher | 60 dB or higher |
| 10 | MHz | 15 | dB | 47 dB | 55 dB |
| 100 | MHz | 5 | dB | 33 dB | 42 dB |
| 1000 | MHz | 0.5 | dB | 3 dB | 20 dB |

TABLE 3

| | | Electromagnetic | Electromagnetic | Electromagnetic |
|---|---|---|---|---|
| | | Wave | Wave | Wave |
| | | Characteristics | Characteristics | Characteristics |
| | | Evaluation | Evaluation | Evaluation |
| KEC method | | Example 1 | Example 2 | Example 3 |
| (Magnetic | | (Mixing | (Mixing | (Mixing |
| Field) | | Percentage: | Percentage: | Percentage: |
| Frequency | | 0.5 wt %) | 10 wt %) | 30 wt %) |
| 1 | MHz | 1 dB or lower | 1 dB or lower | 1 dB or lower |
| 10 | MHz | 1 dB or lower | 1 dB or lower | 1 dB or lower |
| 100 | MHz | 1 dB or lower | 1 dB or lower | 1 dB or lower |
| 1000 | MHz | 1.5 dB | 2.5 dB | 3 dB |

TABLE 4

| | Electromagnetic | Electromagnetic | Electromagnetic |
|---|---|---|---|
| | Wave | Wave | Wave |
| | Characteristics | Characteristics | Characteristics |
| | Evaluation | Evaluation | Evaluation |
| | Example 1 | Example 2 | Example 3 |
| | (Mixing | (Mixing | (Mixing |
| DFFC Method | Percentage: | Percentage: | Percentage: |
| Frequency | 0.5 wt %) | 10 wt %) | 30 wt %) |
| 2 GHz | 1.5 dB | 12 dB | 18 dB |
| 5 GHz | 1.5 dB | 12 dB | 18 dB |
| 8 GHz | 1.5 dB | 12 dB | 18 dB |

TABLE 5

| | Electromagnetic | Electromagnetic | Electromagnetic |
|---|---|---|---|
| | Wave | Wave | Wave |
| | Characteristics | Characteristics | Characteristics |
| | Evaluation | Evaluation | Evaluation |
| FS Method | Example 1 | Example 2 | Example 3 |
| (Absorption | (Mixing | (Mixing | (Mixing |
| characteristics) | Percentage: | Percentage: | Percentage: |
| Frequency | 0.5 wt %) | 10 wt %) | 30 wt %) |
| 50 GHz | 1.5 dB | 8.0 dB | 2.0 dB |
| 70 GHz | 2.0 dB | 6.0 dB | 1.5 dB |
| 80 GHz | 4.0 dB | 6.0 dB | 1.5 dB |

TABLE 6

| | Electromagnetic | Electromagnetic | Electromagnetic |
|---|---|---|---|
| | Wave | Wave | Wave |
| | Characteristics | Characteristics | Characteristics |
| | Evaluation | Evaluation | Evaluation |
| FS Method | Example 1 | Example 2 | Example 3 |
| (Shielding | (Mixing | (Mixing | (Mixing |
| characteristics) | Percentage: | Percentage: | Percentage: |
| Frequency | 0.5 wt %) | 10 wt %) | 30 wt %) |
| 50 GHz | 1.0 dB | 18 dB | 25 dB or higher |
| 70 GHz | 1.0 dB | 19 dB | 25 dB or higher |
| 80 GHz | 1.0 dB | 20 dB | 25 dB or higher |

In most of the evaluation tests excluding the FS method shown in Table 5 (absorption characteristics), a tendency was observed that a higher mixing percentage provides a higher effect of absorbing and shielding electromagnetic waves. Thus, the mixing percentage of about 30 wt % is preferable to enhance the absorbing and shielding effects while maintaining the flexibility. As will be understood from Table 5, to reduce the effect of reflection and enhance the absorbing effect, the mixing percentage may be set to 10 wt % or lower, and the thickness of the electromagnetic wave absorber A1 may be increased or a plurality of electromagnetic wave absorbers A1 may be laminated.

Note that the effect of absorbing and shielding magnetic field of the electromagnetic wave absorber A1 can be enhanced by adding ferrite in addition to the ground carbon particles 2. Also, the electromagnetic wave absorbing effect may be increased by laminating electromagnetic wave absorbers A1 containing ferrite. When a higher flexibility is required, a sheet of electromagnetic wave absorber A1 containing ground carbon particles 2 and another sheet containing ferrite may be laminated. As another means to enhance the electromagnetic wave absorbing effect, a high dielectric such as barium titanate may be added to the electromagnetic wave absorber A1.

The advantages of the electromagnetic wave absorber A1 are described below.

As seen in FIGS. 3 and 4, the ground carbon particles derived from carbon nanotubes (Example) are clearly distinguished by Condition 1 from unground carbon nanotubes (Comparative Example 1) and common types of carbon black (Comparative Examples 2 and 3). This is because the results of measurement by the two different methods on the ground carbon particles obtained by grinding carbon black exhibit a different tendency from those on the unground carbon nanotubes (Comparative Example 1) and those on the carbon black (Comparative Examples 2 and 3) for the following reason. Carbon nanotubes are generally prone to become rigid. Moreover, when carbon nanotubes are ground, each carbon nanotube originally having an elongated cylindrical shape is crushed to some extent and made into smaller fragments. Nevertheless, the carbon nanotubes after grinding are composed of fine particles. This results in that Example is not significantly larger or smaller than Comparative Examples 2 and 3 in terms of the particle size D1, but Example is significantly larger than Comparative Examples 2 and 3 in terms of particle size D2. In addition, Example tends to be smaller than Comparative Example 1 in terms of the particle size D1. This relation is more clearly distinguished when the particle sizes are compared based on the difference (D2−D1) and/or the ratio (D2/D1).

The electromagnetic wave absorber A1 using the ground carbon particles 2 distinguished by Condition 1 has improved stretchability due to the reduced particle size (the difference in particle size D1 from Comparative Example 2) provided by grinding, while also having high electrical conductivity derived from carbon nanotubes. Thus, the electromagnetic wave absorber A1 achieves improvements in stretchability and formability into various shapes along with improvement in electrical conductivity. Accordingly, the electromagnetic wave absorber A1 can provide good electromagnetic-wave absorbing effect under various use conditions. The distinguishment may be made by appropriately combining Condition 2 and Condition 3 with Condition 1, which makes it possible to reliably select ground carbon particles 2 suitable for achieving improvements in stretchability and formability into various shapes along with improvement in electrical conductivity.

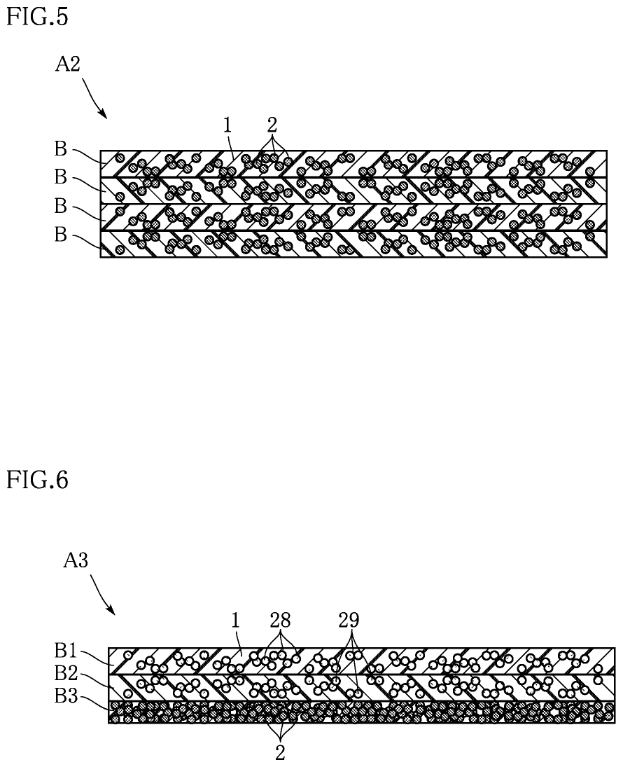

FIG. 5 shows another example of an electromagnetic wave absorber according to the present invention. The electromagnetic wave absorber A2 of the present example is constituted by a plurality of unit layers B. Each unit layer B may have the same configuration as the electromagnetic wave absorber A1 described above. The unit layers B are laminated and secured to each other by bonding, for example. The concentration of ground carbon particles 2 in each unit layer B may differ from each other.

As with the electromagnetic wave absorber A1, the electromagnetic wave absorber A2 also achieves improvements in stretchability and formability into various shapes along with improvement in conductivity. Moreover, the thickness of the electromagnetic wave absorber A2 formed into a sheet can be easily increased. Furthermore, in the thickness direction of the electromagnetic wave absorber A2 having an increased thickness, uneven concentration distribution of the ground carbon particles 2 is prevented.

FIG. 6 shows still another example of an electromagnetic wave absorber according to the present invention. The electromagnetic wave absorber A3 of the present example is constituted by a plurality of unit layers B1, B2, and B3. The unit layers B1, B2, and B3 are laminated and secured to each other by bonding, for example. The concentration of ground carbon particles 2 is higher in the unit layer B3 than in the unit layers B1 and B2. The unit layer B1 contains magnetic particles 28. The magnetic particles 28 may be ferrite particles, for example. The unit layer B2 contains high dielectric particles 29. The concentration of ground carbon particles 2 in the unit layers B1 and B2 is lower than that in the unit layer B3 and may be 0, for example. In the illustrated example, the concentration of ground carbon particles 2 in the unit layers B1 and B2 is 0. The unit layer B1 absorbs electromagnetic waves in a frequency band different from the unit layer B3, and more specifically, absorbs electromagnetic waves in a lower frequency band. The unit layer B2 contributes to an increase in dielectric constant to thereby increase the capacitance component of the constituted RC network. Accordingly, the unit layer B2 can absorb electromagnetic waves in a lower frequency band. Examples of high dielectric of the high dielectric particles 29 include barium titanate, strontium titanate, calcium titanate, magnesium titanate, zinc titanate, lanthanum titanate, neodymium titanate, lead titanate, barium zirconate, calcium zirconate, barium tin oxide, calcium tin oxide and magnesium silicate, and these may be used alone or in mixtures of two or more.

As with the electromagnetic wave absorbers A1 and A2, the electromagnetic wave absorber A3 also achieves improvements in stretchability and formability into various shapes along with improvement in conductivity. As will be understood from the present example, when the electromagnetic wave absorber according to the present invention is formed into a sheet, the specific configuration is not limited. Inclusion of the unit layer B1 in addition to the unit layer B3 allows absorption of electromagnetic waves in a wider frequency band.

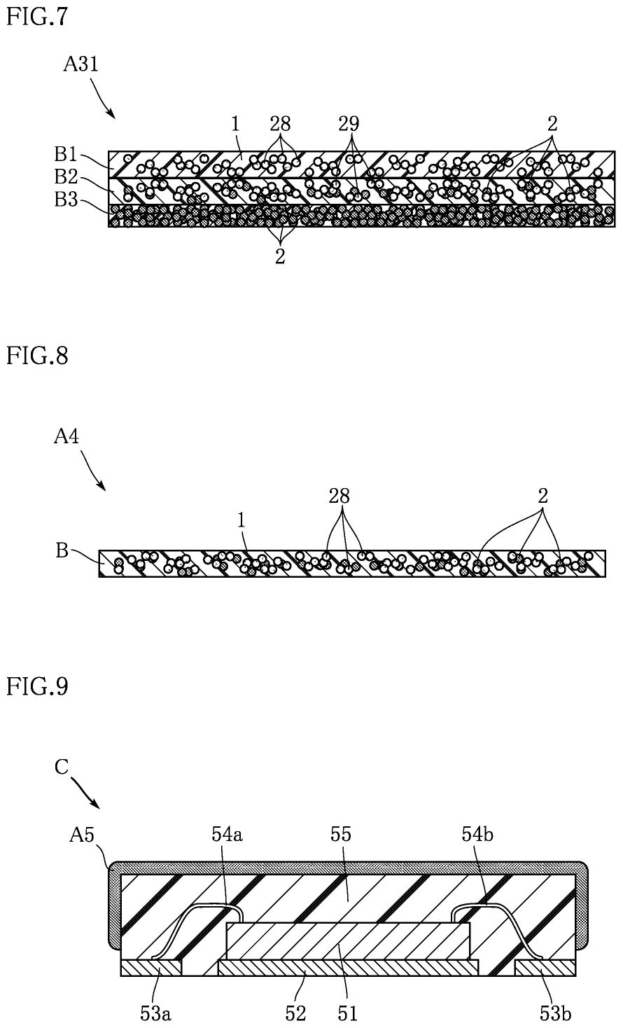

FIG. 7 shows still another example of an electromagnetic wave absorber according to the present invention. As with the electromagnetic wave absorber A3 described above, the electromagnetic wave absorber A31 of the present example is constituted by a plurality of unit layers B1, B2, and B3. The electromagnetic wave absorber 31 differs from the electromagnetic wave absorber A3 in configuration of the unit layer B2.

The unit layer B2 of the present example contains both the high dielectric particles 29 and ground carbon particles 2. The concentration of ground carbon particles 2 in the unit layer B2 is lower than that in the unit layer B3. As with the electromagnetic wave absorbers A1 and A2, the electromagnetic wave absorber A31 also achieves improvements in stretchability and formability into various shapes along with improvement in conductivity. As will be understood from the present example, when the electromagnetic wave absorber according to the present invention is formed into a sheet, the specific configuration is not limited.

FIG. 8 shows still another example of an electromagnetic wave absorber according to the present invention. The electromagnetic wave absorber A4 of the present example is constituted y a unit layer B. The unit layer B of the present example contains magnetic particles 28 and ground carbon particles 2. According to the electromagnetic wave absorber 4, it is possible to absorb electromagnetic waves in a wider frequency band with a configuration constituted by a single unit layer B.

FIG. 9 shows an example of an electronic device to which an electromagnetic wave absorbing coating according to the present invention is applied. The electronic device C of the present embodiment includes an electronic element 51, a plurality of leads 52, 53a and 53b, wires 54a and 54b, a resin part 55, and an electromagnetic wave absorber A5.

The electronic element 51 is made using a semiconductor, for example, and performs various electronic functions. The leads 52, 53a and 53b are conductive members made of metal such as Cu, for example. The electronic element 51 is mounted on the lead 52. One end of the wire 54a is bonded to the lead 53a. One end of the wire 54b is bonded to the lead 53b. The wires 54a and 54b are made of metal such as Au, and the other end of each of these wires is bonded to the electronic element 51. The resin part 55 covers the electronic element 51, a part of each of the leads 52, 53a and 53b, and the wires 54a and 54b, and is an insulating member made of epoxy resin, for example.

The electromagnetic wave absorber A5 covers a constituent element of the electronic device C and covers the resin part 55 in the illustrated example. The electromagnetic wave absorber A5 includes a base 1 and ground carbon particles 2, as with the electromagnetic wave absorber A1, A2 and A3 described above. The electromagnetic wave absorber A5 is formed by a coating process. The electromagnetic wave absorber A5 is formed at a position away from the leads 53a and 53b. This is to avoid a short-circuit between the lead 53a and the lead 53b.

To form the electromagnetic wave absorber A5 by a coating process, an electromagnetic wave absorbing coating is applied. The electromagnetic wave absorbing coating contains a paste material or a liquid material to become the substrate 1, and ground carbon particles 2 are mixed in the paste material or the liquid material. Examples of the paste material include silicone grease, and high-viscosity silicone grease is preferable.

The electronic device C is provided with the electromagnetic wave absorber A5. Thus, it is possible to prevent leakage of electromagnetic waves from the electronic device C and prevent external electromagnetic noise from reaching the electronic element 51. Forming the electromagnetic wave absorber A5 by a coating process makes it possible to reliably cover the electronic device C with the electromagnetic wave absorber A5 even when the shape of the resin part 55 or other parts of the electronic device C is complicated. Moreover, even when the shape of the electronic device C changes due to mechanical stress or thermal expansion, generation of cracks in the electromagnetic wave absorber A5 can be prevented. Thus, damage to a network can be avoided, and the properties can be maintained.

A resin component according to the present invention includes a component body made of resin and an electromagnetic wave absorbing coating covering at least a part of the component body. As the electromagnetic wave absorbing coating, the electromagnetic wave absorbing coating in the foregoing embodiment may be used appropriately. The component body is not limited and may include automotive parts such as a bumper and electronic device parts such as a cell phone housing, for example.

By covering at least a part of the component body with an electromagnetic wave absorbing coating, the effect of shielding electromagnetic noise for the equipment or device to which the resin component is applied is enhanced, and the weight is reduced as compared with the structure that uses e.g., a metal part to shield electromagnetic noise.

The electromagnetic wave absorber, electromagnetic wave absorbing coating, electronic device, and resin component according to the present invention are not limited to the foregoing embodiments. The electromagnetic wave absorber and the specific structure of the electromagnetic wave absorber, electromagnetic wave absorbing coating and electronic device may be varied in design in many ways.

1. An electromagnetic wave absorber comprising ground carbon particles derived from carbon nanotubes.

2. The electromagnetic wave absorber according to claim 1, wherein the ground carbon particles have a particle size of 0.5 μm to 1.5 μm as measured by dynamic light scattering and a particle size of 15 μm to 70 μm as measured by laser scattering.

3. The electromagnetic wave absorber according to claim 2, wherein a difference between the particle size as measured by dynamic light scattering and the particle size as measured by laser scattering of the ground carbon particles is 15 μm or larger.

4. The electromagnetic wave absorber according to claim 1, wherein the electromagnetic wave absorber is formed into a sheet.

5. The electromagnetic wave absorber according to claim 4, wherein the electromagnetic wave absorber is formed into a sheet made up of a plurality of laminated layers.

6. The electromagnetic wave absorber according to claim 5, wherein the layers include a layer containing the ground carbon particles at a higher concentration than remaining one or ones of the layers.

7. The electromagnetic wave absorber according to claim 6, wherein the layers include a layer that absorbs electromagnetic waves in a frequency band different from the layer containing the ground carbon particles at a higher concentration.

8. The electromagnetic wave absorber according to claim 7, wherein the layers include at least one of a layer containing a magnetic material and a layer containing high dielectric.

9. An electromagnetic wave absorbing coating comprising ground carbon particles derived from carbon nanotubes.

10. The electromagnetic wave absorbing coating according to claim 9, wherein the ground carbon particles have a particle size of 0.5 μm to 1.5 μm as measured by dynamic light scattering and a particle size of 15 μm to 70 μm as measured by laser scattering.

11. The electromagnetic wave absorbing coating according to claim 10, wherein a difference between the particle size as measured by dynamic light scattering and the particle size as measured by laser scattering of the ground carbon particles is 15 μm or larger.

12. An electronic device to which the electromagnetic wave absorbing coating according to claim 9 is applied.

13. A resin component to which the electromagnetic wave absorbing coating according to claim 9 is applied.
